(19) United States
(12) Patent Application Publication
(10) Pub. No.: US 2009/0250690 A1
(43) Pub. Date: Oct. 8, 2009

(54) ORGANIC THIN FILM TRANSISTOR SUBSTRATE AND METHOD OF MANUFACTURING THE SAME

(75) Inventors: Jung-Han SHIN, Yongin-si (KR); Seung-Hwan CHO, Suwon-si (KR); Seong-Sik SHIN, Cupertino, CA (US); Keun-Kyu SONG, Yongin-si (KR); Jung-Hun NOH, Yongin-si (KR)

Correspondence Address: H.C. PARK & ASSOCIATES, PLC, 8500 LEESBURG PIKE, SUITE 7500, VIENNA, VA, 22182, US

(73) Assignee: SAMSUNG ELECTRICS CO., LTD., Suwon-si (KR)

(21) Appl. No.: 12/326,650

(22) Filed: Dec. 2, 2008

(30) Foreign Application Priority Data
Feb. 21, 2008 (KR) 10-2008-0015830

(51) Int. Cl. H01L 51/05; H01L 51/40

(52) U.S. Cl. 257/40; 438/99; 257/E51.006; 257/E21.459

(57) ABSTRACT

In an organic thin film transistor (TFT) substrate, the organic TFT substrate includes gate lines, data lines, a gate electrode, a source electrode, a drain electrode, a gate insulating layer, an organic semiconductor layer, and an organic protective layer. The gate and data lines are insulated from each other and cross each other to define pixel areas. The gate electrode is connected to the gate line. The source electrode is connected to the data line. The drain electrode faces the source electrode with the gate electrode disposed therebetween. The gate insulating layer covers the gate electrode and exposes a portion of the source and drain electrodes. The organic semiconductor layer contacts the source and drain electrodes. The organic protective layer is disposed on the organic semiconductor layer to protect the organic semiconductor layer.

### CROSS-REFERENCE TO RELATED APPLICATION

This application claims priority from and the benefit of Korean Patent Application No. 10-2008-0015830, filed on Feb. 21, 2008, which is hereby incorporated by reference for all purposes set forth herein.

### BACKGROUND OF INVENTION

1. Field of the Invention

The present invention relates to an organic thin film transistor (TFT) substrate. More particularly, the present invention relates to an organic TFT substrate and a simplified method of manufacturing the organic TFT substrate.

2. Discussion of the Background

With the development of information technologies, the demand for high-performance display apparatuses capable of displaying various types of information, such as videos, graphics, and characters, has greatly increased. In response to this demand, the display industry has rapidly grown.

Particularly, since a liquid crystal display (LCD) has low power consumption, is slim and lightweight, and suppresses harmful electromagnetic waves as compared with a cathode ray tube (CRT), the LCD has been greatly advanced for several years as a next-generation high-technology display apparatus. In addition, the LCD has been extensively employed in various fields such as electronic clocks, electronic calculators, personal computers (PCs), and televisions (TVs). In such an LCD, liquid crystal cells arranged in a matrix type in a liquid crystal panel adjust light transmittance according to video signals, so that an image may be displayed.

Each liquid crystal cell uses a TFT as a switching device to independently supply video signals. An active layer of such a TFT may include amorphous silicon or poly silicon.

However, since an active layer including amorphous silicon or poly silicon is generally patterned through a thin film deposition process, a photolithography process, and an etching process, the manufacturing process may be complicated and costly.

In this regard, research has been actively conducted to provide an organic TFT including an organic semiconductor layer, which may be formed through a printing process, as an active layer. However, since a process of forming an organic TFT substrate uses masks when forming a gate metal pattern and a data metal pattern, the manufacturing cost may increase and additional processes my be required.

### SUMMARY OF INVENTION

The present invention provides an organic thin film transistor (TFT) substrate that may be made by a simplified manufacturing process.

The present invention also provides a method of manufacturing the organic TFT substrate.

Additional features of the invention will be set forth in the description which follows, and in part will be apparent from the description, or may be learned by practice of the invention.

The present invention discloses an organic TFT substrate including gate lines, data lines, a gate electrode, a source electrode, a drain electrode, a gate insulating layer, an organic semiconductor layer, and an organic protective layer. The gate lines and data lines are insulated from each other and cross each other to define pixel areas. The gate electrode is connected to the gate line. The source electrode is connected to the data line. The drain electrode faces the source electrode with the gate electrode disposed therebetween. The gate insulating layer covers the gate electrode while exposing a portion of the source and drain electrodes. The organic semiconductor layer contacts the source and drain electrodes. The organic protective layer is disposed on the organic semiconductor layer to protect the organic semiconductor layer.

The present invention also discloses a method of manufacturing an organic TFT substrate including forming gate lines, data lines, a gate electrode, a source electrode, and a drain electrode on a same plane of a substrate. A gate insulating layer is formed to cover the gate electrode wand expose a portion of the source and drain electrodes. An organic semiconductor layer contacts the source and drain electrodes. An organic protective layer is formed on the organic semiconductor layer.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the principles of the invention.

FIG. 1 is a plan view showing an organic TFT substrate according to an exemplary embodiment of the present invention.

FIG. 2 is a sectional view of an organic TFT substrate taken along line I-I′ of FIG. 1.

FIG. 3 is a plan view showing an organic TFT substrate according to another exemplary embodiment of the present invention.

FIG. 4 is a sectional view of the organic TFT substrate taken along line I-I′ of FIG. 3.

FIG. 5, FIG. 6, FIG. 7, FIG. 8, FIG. 9, and FIG. 10 are sectional views showing a method of manufacturing an organic TFT substrate according to an exemplary embodiment of the present invention.

FIG. 11 is a sectional view showing a conductive pattern of an organic TFT substrate according to another exemplary embodiment of the present invention.

FIG. 12 is a sectional view showing a step of forming an insulating layer of a method of manufacturing an organic TFT substrate according to an exemplary embodiment of the present invention.

FIG. 13 is a sectional view showing a step of forming a bank insulating layer of a method of manufacturing an organic TFT substrate according to an exemplary embodiment of the present invention.

FIG. 14 is a plan view showing the process of FIG. 5 in a method of manufacturing an organic TFT substrate according to an exemplary embodiment of the present invention.

FIG. 15 is a plan view showing the process of FIG. 6 in a method of manufacturing the organic TFT substrate according to an exemplary embodiment of the present invention.

FIG. 16 is a plan view showing the process of FIG. 9 in a method of manufacturing the organic TFT substrate according to an exemplary embodiment of the present invention.

FIG. 17 is a plan view showing the process of FIG. 10 in a method of manufacturing the organic TFT substrate according to an exemplary embodiment of the present invention.

### DETAILED DESCRIPTION OF THE ILLUSTRATED EMBODIMENTS

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure is thorough, and will fully convey the scope of the invention to those skilled in the art. In the drawings, the size and relative sizes of layers and regions may be exaggerated for clarity.

It will be understood that when an element or layer is referred to as being “on,” “connected to,” or “coupled to” another element or layer, it can be directly on, directly connected to, or directly coupled to the other element or layer or intervening elements or layers may be present. In contrast, when an element is referred to as being “directly on,” “directly connected to,” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, etc. may be used herein to describe various elements, components, regions, layers, and/or sections, these elements, components, regions, layers, and/or sections should not be limited by these terms. These terms are only used to distinguish one element, component, region, layer, or section from another region, layer, or section.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms, “a”, “an,” and “the” are intended to include the plural forms as well, unless the context clearly indicates otherwise. It will be further understood that the terms “includes” and/or “including”, when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, exemplary embodiments of the present invention will be explained in detail with reference to the accompanying drawings.

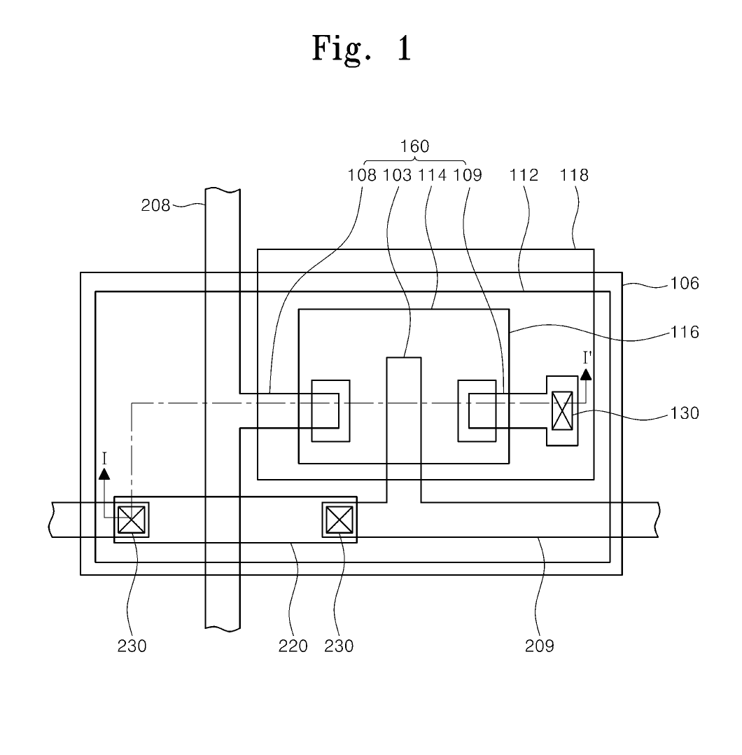

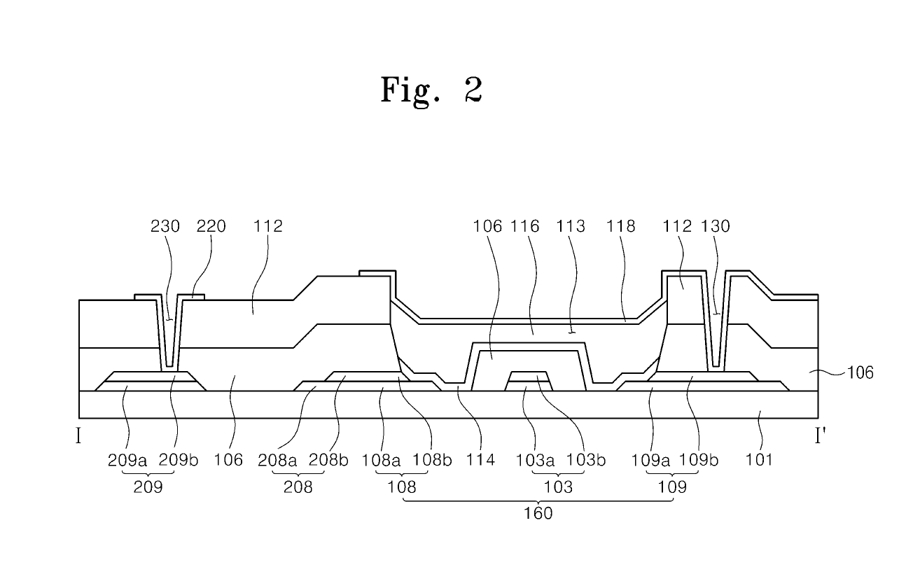

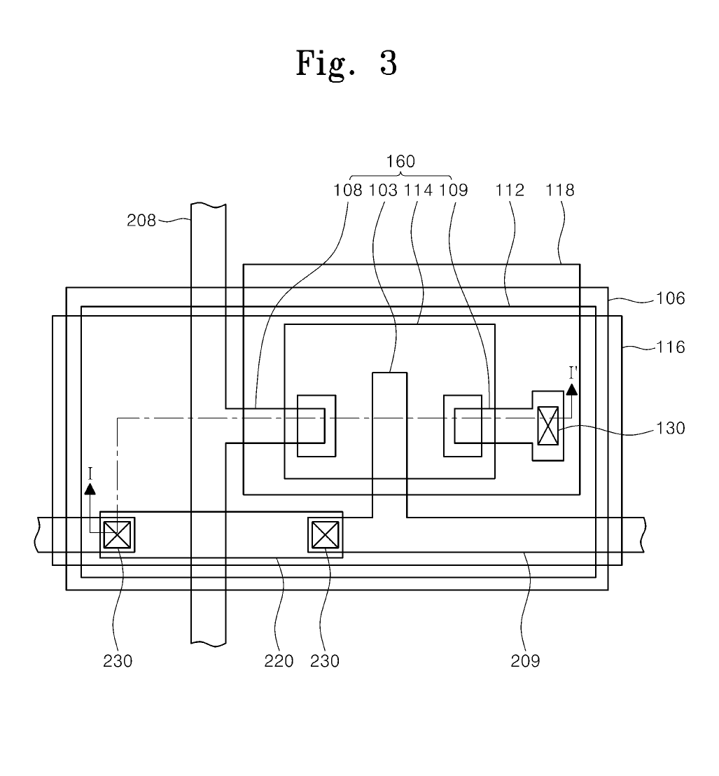

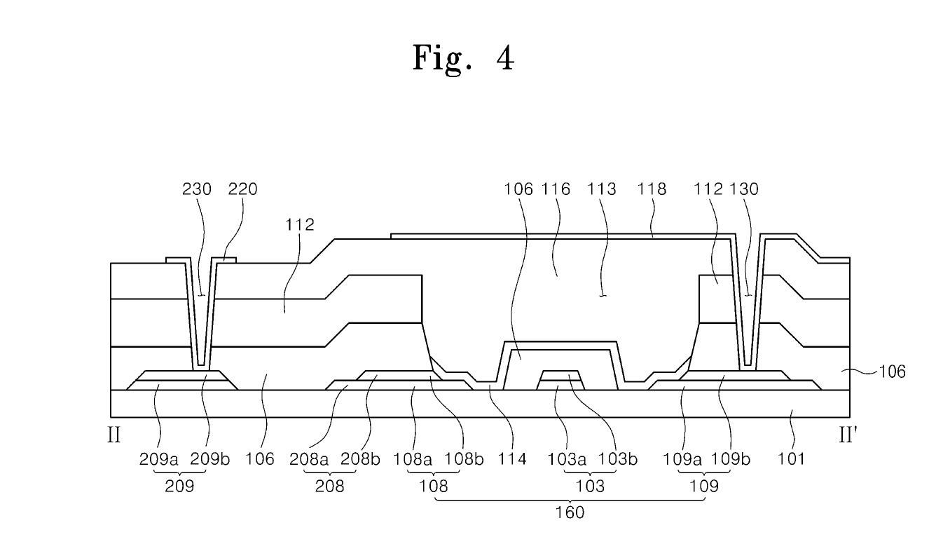

FIG. 1 is a plan view showing an organic TFT substrate according to an exemplary embodiment of the present invention and FIG. 2 is a sectional view of the organic TFT substrate taken along line I-I′ of FIG. 1. FIG. 3 is a plan view showing an organic TFT substrate according to another exemplary embodiment of the present invention and FIG. 4 is a sectional view of the organic TFT substrate taken along line I-I′ of FIG. 3.

Referring to FIG. 1 and FIG. 2, an organic TFT substrate includes gate lines 209, data lines 208, and an organic TFT 160 connected with the gate and data lines 209 and 208. The gate and data lines 209 and 208 are formed on the same plane on a substrate 101. Further, the organic TFT substrate includes a pixel electrode 118 formed in a sub-pixel area defined by the gate and data lines 209 and 208 so that the pixel electrode 118 is connected with the organic TFT 160.

The gate line 209 receives a scan signal from a gate driver (not shown) and the data line 208 receives a pixel signal from a data driver (not shown). The gate and data lines 209 and 208 have a double layer structure. Particularly, the gate lines 209 include a first conductive layer 209a and a second conductive layer 209b that are stacked on the substrate 101, and the data lines 208 include a first conductive layer 208a and a second conductive layer 208b that are stacked on the substrate 101. Although not shown in FIG. 1 and FIG. 2, the gate and data lines 209 and 208 may each have a single layer structure including only the respective first conductive layer 209a and 208a. The first conductive layers 209a and 208a of the gate and data lines 209 and 208 may be transparent conductive layers and the second conductive layers 209b and 208b thereof may include an opaque metal layer. For example, the first conductive layers 209a and 208a may each be a transparent conductive layer, such as indium tin oxide (ITO), tin oxide (TO), indium zinc oxide (IZO), or indium tin zinc oxide (ITZO). The second conductive layers 209b and 208b may include copper, molybdenum, aluminum, a copper alloy, a molybdenum alloy, or an aluminum alloy.

When the organic TFT 160 is turned on and off, an insulating layer 106 may improve on-current and off-current characteristics of the organic TFT 160. The insulating layer 106 may include an inorganic insulating layer including inorganic substances or an organic insulating layer including organic substances. For example, the inorganic insulating layer may include silicon nitride (SiNₓ). Further, the organic insulating layer may include an organic substance such as polyvinylpyrrolidone (PVP), polyvinylacetate (PVA), phenolic polymer, acrylic polymer, imide polymer, fluorine polymer, or vinylalcohol polymer. The insulating layer 106 is patterned through photolithography and etching processes to cover a gate electrode 103 and partially exposes source and drain electrodes 108 and 109 to form a channel.

A bank insulating layer 112 is formed on the insulating layer 106 on the source and drain electrodes 108 and 109, and forms a hole 113 together with the insulating layer 106. The hole 113 formed by the bank insulating layer 112 and the insulating layer 106 exposes a part of the source and drain electrodes 108 and 109 to form the channel. The parts of the source and drain electrodes 108 and 109, which are exposed by the bank insulating layer 112 and the insulating layer 106, are connected with an organic semiconductor layer 114. The bank insulating layer 112 may include a photosensitive organic substance and may be treated with fluorine plasma. Thus, since the bank insulating layer 112 has water-resistant and oil-resistant characteristics, the plasma-processed bank insulating layer 112 allows a liquid-phase organic semiconductor to be easily defined within the bank insulating layer 112 when forming the organic semiconductor layer 114.

The organic TFT 160 allows the pixel signal supplied to the data line 208 to be charged to the pixel electrode 118 in response to the scan signal supplied to the gate line 209. To this end, the organic TFT 160 includes the gate electrode 103 connected to the gate line 209, the source electrode 108 connected to the data line 208, and the drain electrode 109 facing the source electrode 108 with the gate electrode 103 disposed therebetween and connected to the pixel electrode 118. Further, the organic TFT 160 includes the organic semiconductor layer 114 that overlaps the gate electrode 103 with the insulating layer 106 disposed therebetween to form the channel between the source and drain electrodes 108 and 109.

The organic semiconductor layer 114 is formed on the source and drain electrodes 108 and 109 and in the hole 113, which is formed by the bank insulating layer 112 and the insulating layer 106, in an overlapping area with the gate electrode 103. The organic semiconductor layer 114 includes an organic semiconductor substance such as pentacene, tetracene, anthracene, naphthalene, α-6T, α-4T, perylene, derivative of the perylene, rubrene, derivative of the rubrene, coronene, derivative of the coronene, perylene tetracarbocylic diimide, derivative of the perylene tetracarbocylic diimide, naphthalene tetracarboxylic dianhydride, derivative of the naphthalene tetracarboxylic dianhydride, a conjugated polymer derivative containing substituted or non-substituted thiophene, or a conjugated polymer derivative containing substituted fluorine.

The organic semiconductor layer 114 makes ohmic contact with the source and drain electrodes 108 and 109 through a self-assembled monolayer (SAM) process. In detail, the work function difference between the source/drain electrodes 108 and 109 and the organic semiconductor layer 114 is reduced through the self-assembled monolayer process. Thus, holes may be easily injected from the source and drain electrodes 108 and 109 to the organic semiconductor layer 114, so that contact resistance between the source and drain electrodes 108 and 109 and the organic semiconductor layer 114 may be reduced.

An organic protective layer 116 is formed on the organic TFT 160 to protect the organic TFT 160. As shown in FIG. 1 and FIG. 2, the organic protective layer 116 is formed in the hole 113 formed by the bank insulating layer 112 and the insulating layer 106. Alternatively, as shown in FIG. 3 and FIG. 4, the organic protective layer 116 could be formed to cover the entire surface of the organic TFT 160 and the bank insulating layer 112.

The pixel electrode 118 is formed on the organic protective layer 116 and the bank insulating layer 112 and is connected with the drain electrode 109 through a first contact hole 130 that exposes a portion of the drain electrode 109 and is formed through the bank insulating layer 112 and the insulating layer 106. Meanwhile, as shown in FIG. 3 and FIG. 4, when the organic protective layer 116 covers the entire surface of the organic TFT 160 and the bank insulating layer 112, the pixel electrode 118 is formed on the organic protective layer 116, and is connected to the drain electrode 109 through the first contact hole 130, which exposes a part of the drain electrode 109 and is formed through the organic protective layer 116, the bank insulating layer 112, and the insulating layer 106. Further, the pixel electrode 118 supplies a voltage to liquid crystal molecules formed between the organic TFT substrate and a color filter substrate (not shown).

The gate lines 209 are spaced apart from each other with the data lines 208 disposed therebetween, and a gate bridge 220 is formed on the bank insulating layer 112 to interconnect the gate lines 209. The gate bridge 220 is insulated from the data lines 208 and connected with the gate lines 209 through second contact holes 230.

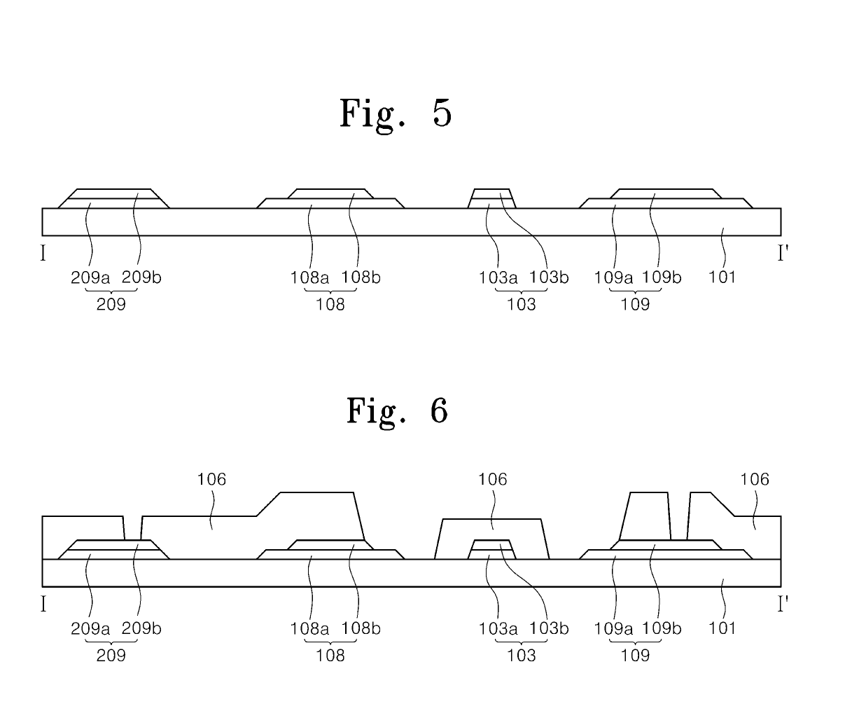

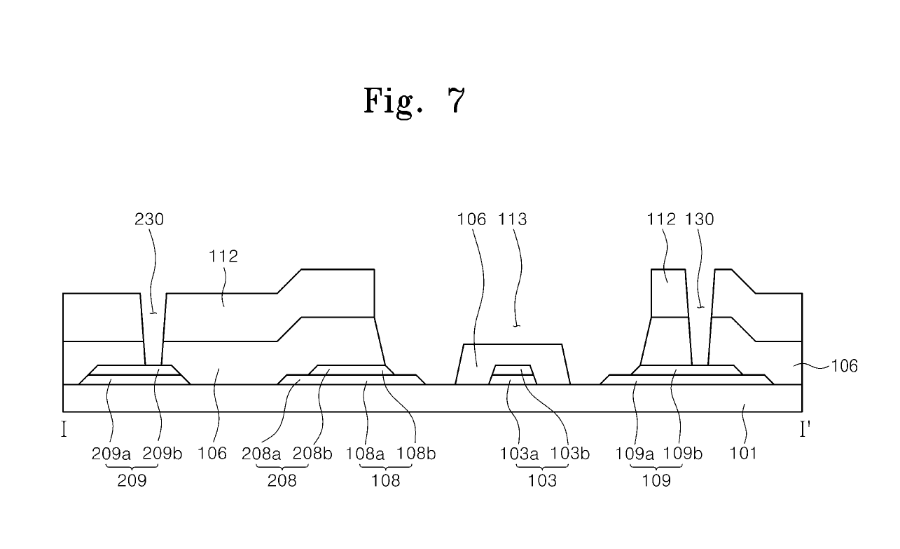

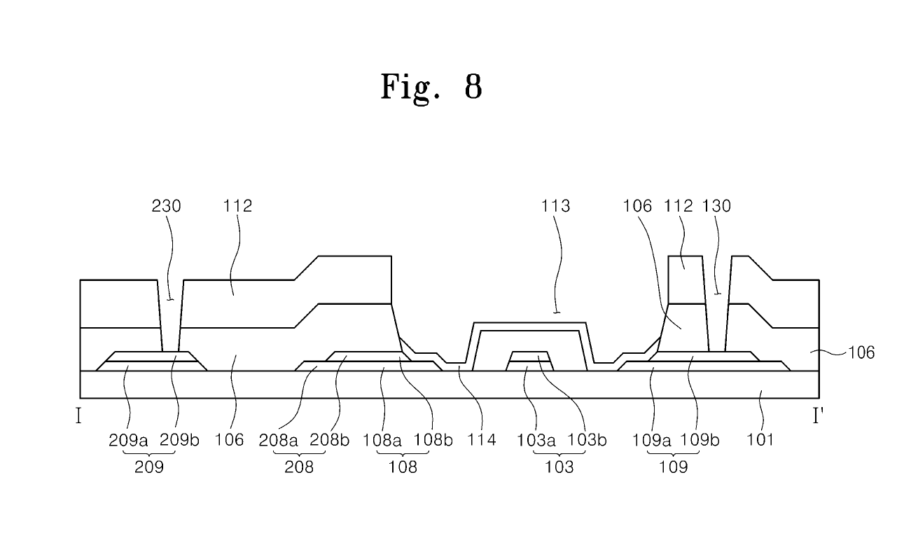

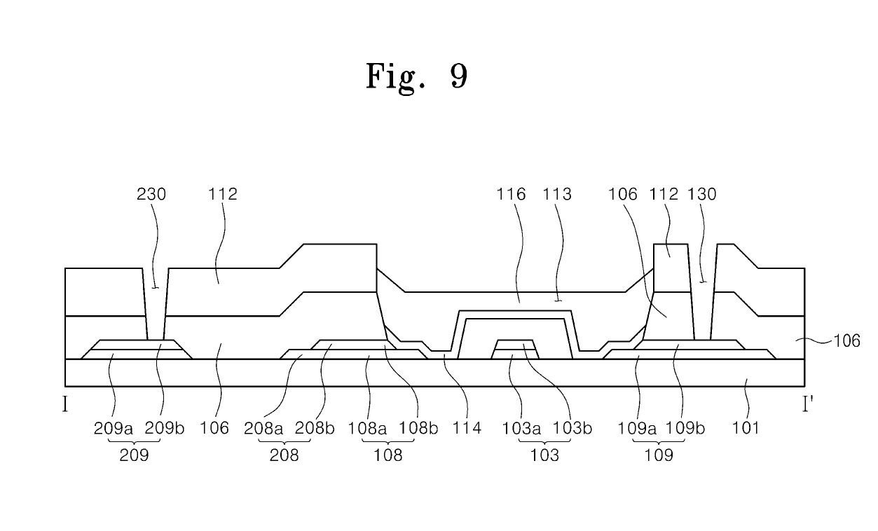

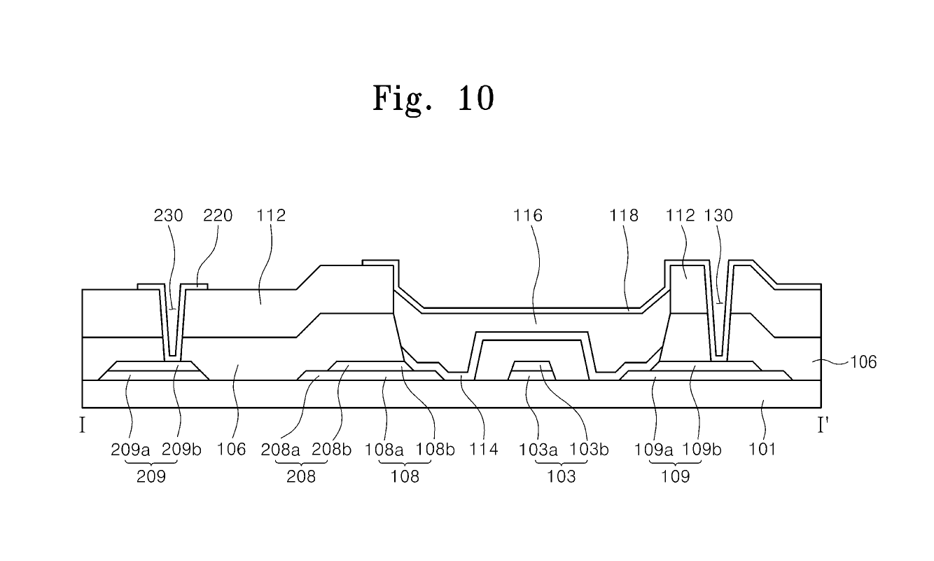

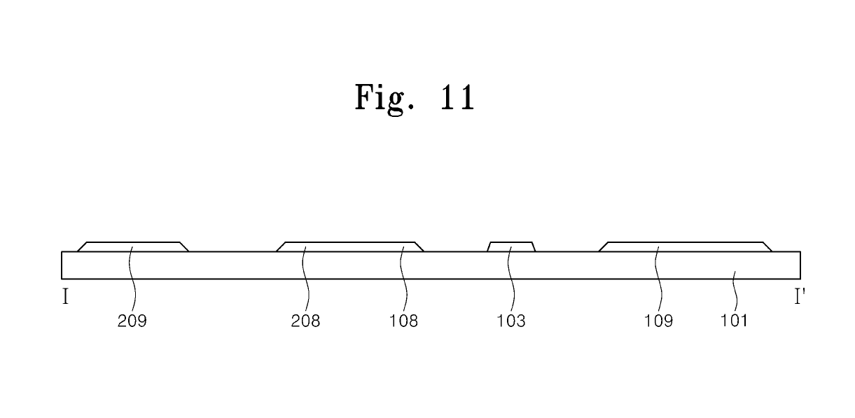

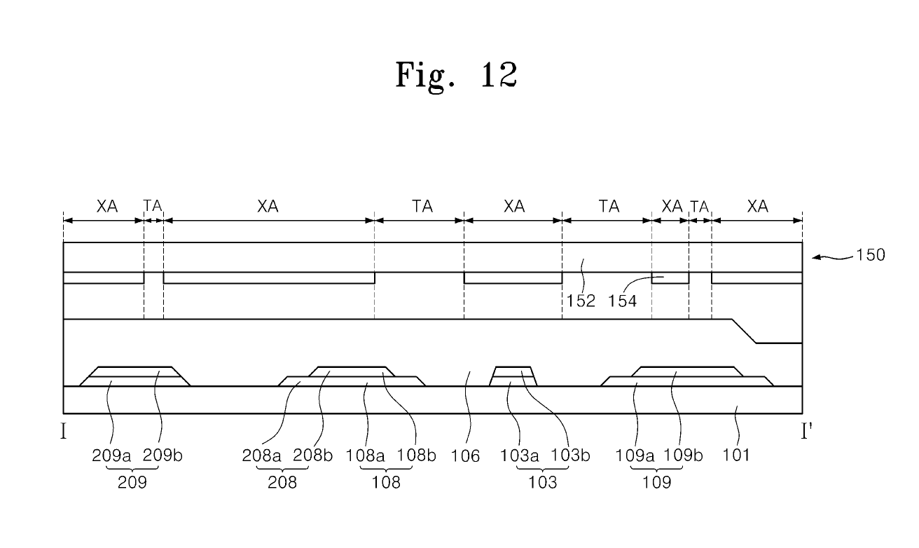

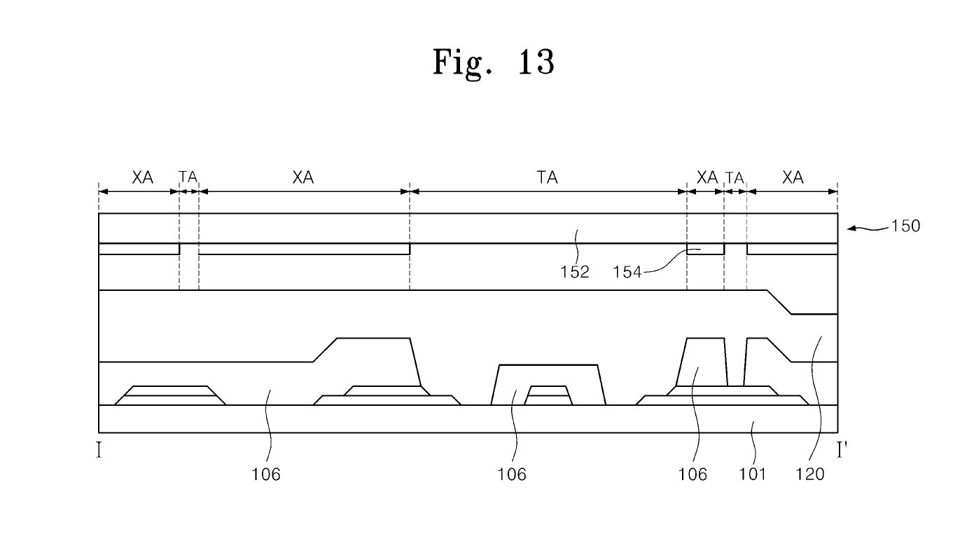

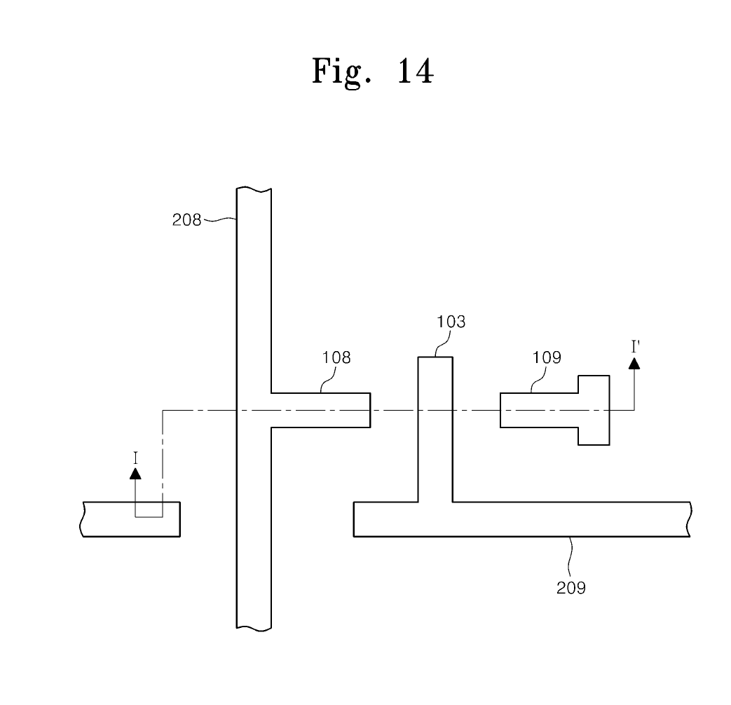

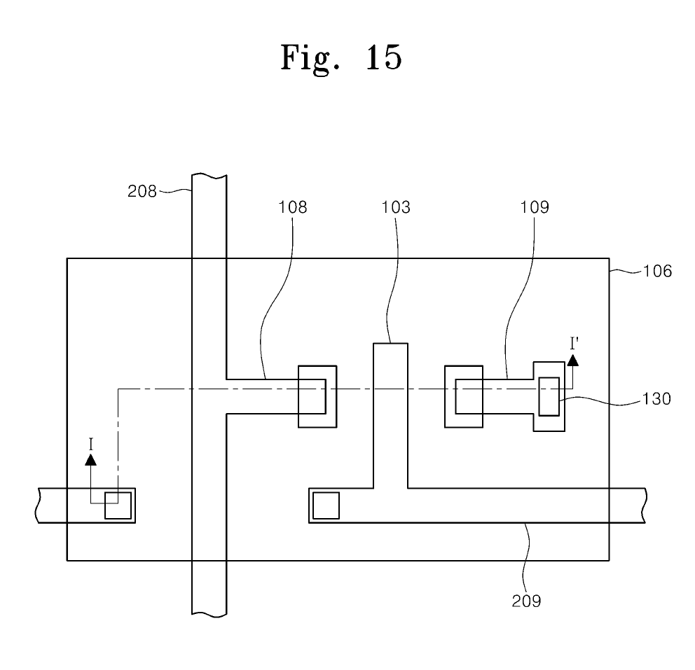

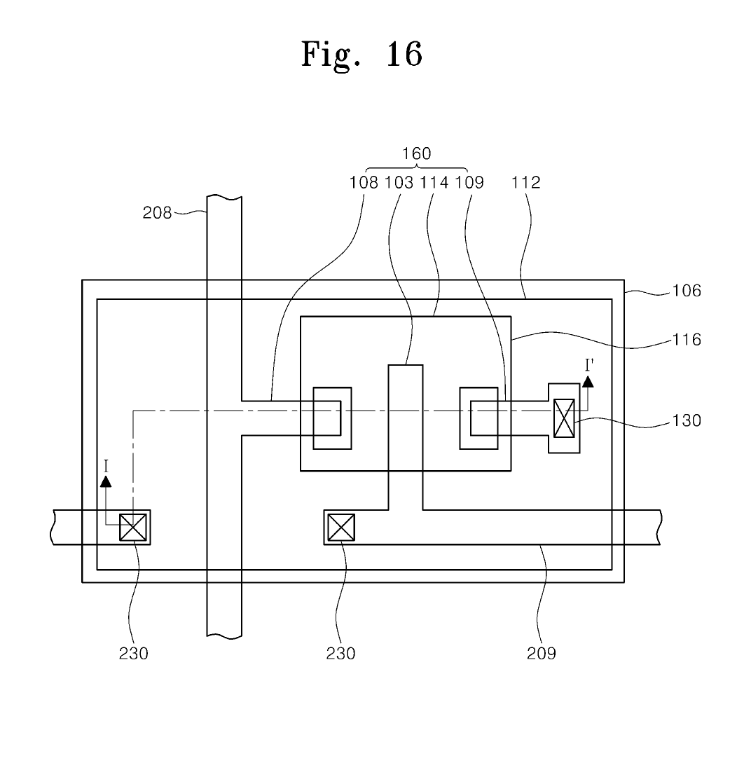

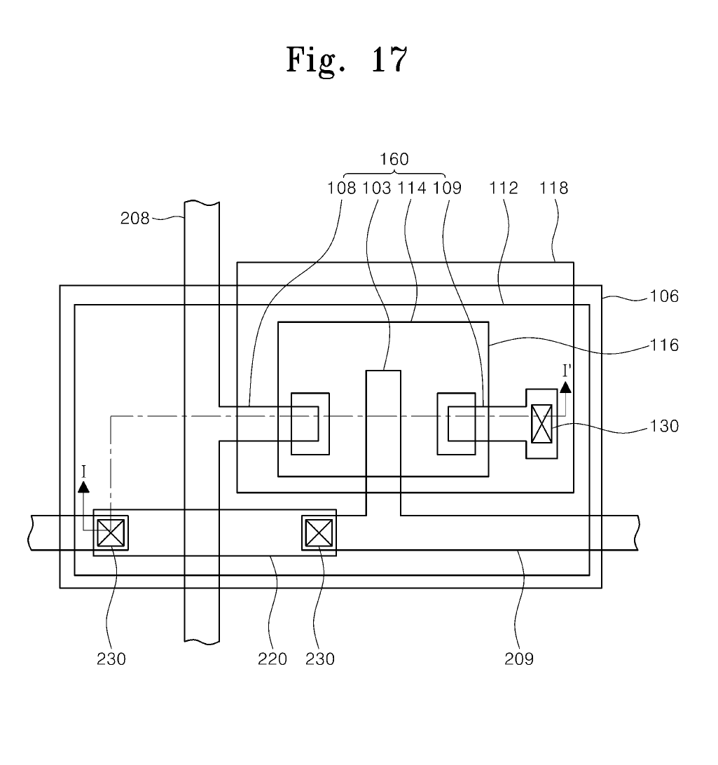

Hereinafter, the method of manufacturing the organic TFT substrate according to one exemplary embodiment of the present invention will be described with reference to FIG. 5, FIG. 6, FIG. 7, FIG. 8, FIG. 9, FIG. 10, FIG. 11, FIG. 12, FIG. 13, FIG. 14, FIG. 15, FIG. 16, and FIG. 17.

FIG. 5, FIG. 6, FIG. 7, FIG. 8, FIG. 9, and FIG. 10 are sectional views showing the method of manufacturing the organic TFT substrate according to one exemplary embodiment of the present invention. FIG. 14 is a plan view showing the process of FIG. 5 in the method of manufacturing the organic TFT substrate according to one exemplary embodiment of the present invention, FIG. 15 is a plan view showing the process of FIG. 6 in the method of manufacturing the organic TFT substrate according to one exemplary embodiment of the present invention, FIG. 16 is a plan view showing the process of FIG. 9 in the method of manufacturing the organic TFT substrate according to one exemplary embodiment of the present invention, and FIG. 17 is a plan view showing the process of FIG. 10 in the method of manufacturing the organic TFT substrate according to one exemplary embodiment of the present invention.

As shown in FIG. 5 and FIG. 14, a conductive pattern is formed on the substrate 101. The conductive pattern includes the gate lines 209 including the first and second conductive layers 209a and 209b, the data lines 208, the gate electrode 103, the source electrode 108, and the drain electrode 109.

In detail, first and second conductive layers are sequentially stacked on the substrate 101 through a deposition method including sputtering. After stacking the first and second conductive layers, the first and second conductive layers are patterned through the photolithography and etching processes, thereby forming the conductive pattern including the gate line 209, the gate electrode 103, the source electrode 108, and the drain electrode 109. The first conductive layer may include ITO and the second conductive layer may include a metal material such as aluminum, molybdenum, chrome, or copper.

Alternatively, as shown in FIG. 11, the conductive pattern may be formed on the substrate 101 as a single layer structure, in which the conductive pattern includes the gate lines 209, the data lines 208, the gate electrode 103, the source electrode 108, and the drain electrode 109.

As described above, the conductive pattern according to the present exemplary embodiment may have a single layer structure including the first conductive layer or a double layer structure including the first and second conductive layers that are stacked.

In exemplary embodiments of the present invention, the gate and data patterns are simultaneously formed using only one mask differently from the conventional method of forming the gate and data patterns using separate masks, thereby simplifying the manufacturing process by reducing the number of masks.

Then, as shown in FIG. 6 and FIG. 15, the insulating layer 106 is formed on the substrate 101 having the conductive pattern. In detail, as shown in FIG. 12, the inorganic insulating substance or organic insulating substance is deposited on the entire surface of the substrate 101 having the conductive pattern. The insulating layer 106 may include an inorganic insulating substance, such as silicon nitride SiNₓ, and may be formed through a deposition method including a plasma enhanced chemical vapor deposition (PECVD). Further, the insulating layer 106 may include an organic insulating substance such as polyvinylptyrrolidone (PVP) and may be made through a spin coating method. Then, a mask 150 is aligned on the substrate 101. The mask 150 includes a blocking area XA, in which a blocking layer 154 is formed on a quartz substrate 152, and a transmitting area TA in which only the quartz substrate 152 exists. The blocking area XA blocks ultraviolet rays during an exposure process, and thus the insulating layer 106 is formed on a region of the substrate 101 that corresponds to the blocking area XA, after a development process. As described above, the insulating layer 106 is patterned through the photolithography and etching processes to cover the gate electrode 103, and the source and drain electrodes 108 and 109 are partially exposed to form the channel. The insulating layer 106 formed on drain electrode 109 is partially exposed to form the first contact hole 130. Further, second contact holes 230 are formed in the insulating layer 106 to expose the gate lines 209.

Then, as shown in FIG. 7, the bank insulating layer 112 is formed on the substrate 101 having the insulating layer 106. In detail, as shown in FIG. 13, photosensitive organic insulating substance 120 is coated on the entire surface of the substrate 101 through a spinless or spin coating method. Then, the mask 150 is aligned on the substrate 101. The mask 150 includes the blocking area XA, in which the blocking layer 154 is formed on the quartz substrate 152, and the transmitting area TA in which only the quartz substrate 152 exists. The blocking area XA blocks ultraviolet rays during an exposure process, and thus the bank insulating layer 112 is formed on a region of the substrate 101 that corresponds to the blocking area XA, after a development process. The hole 113 exposes the insulating layer 106, the source electrode 108, and the drain electrode 109. Further, the bank insulating layer 112 is treated with fluorine. Thus, since the bank insulating layer 112 has water-resistant and oil-resistant characteristics, the bank insulating layer 112 may allow the liquid-phase organic semiconductor to be easily defined within the bank insulating layer 112 when forming the organic semiconductor layer 114.

Then, as shown in FIG. 8, the liquid-phase organic semiconductor is injected into the hole 113, which is formed by the bank insulating layer 112 and the insulating layer 106, using an inkjet spray device. The liquid-phase organic semiconductor is cured, so that the solid-phase organic semiconductor layer 114 is formed. Then, the organic semiconductor layer 114 is subject to the SAM processing. Thus, the organic semiconductor layer 114 makes ohmic contact with the source and drain electrodes 108 and 109. Then, organic insulating solution such as polyvinylacetate (PVA) is injected into the hole 113, which is formed by the bank insulating layer 112, through the inkjet spray device, and then cured, so that the organic protective layer 116 is formed.

As shown in FIG. 9 and FIG. 16, the organic protective layer 116 is formed in the hole 113 formed by the bank insulating layer 112 and the insulating layer 106. Next, as shown in FIG. 10, the pixel electrode 118 is formed on the organic protective layer 116 and the bank insulating layer 112. At this time, the pixel electrode 118 is connected with the drain electrode 109 through the first contact hole 130.

Further, as shown in FIG. 10 and FIG. 17, the gate bridge 220 is formed on the bank insulating layer 112. The gate bridge 220 interconnects the gate lines 209, which are spaced apart from each other with the data lines 208 disposed therebetween, through the second contact holes 230.

According to the organic TFT substrate and the method of manufacturing the organic TFT substrate, gate, source, and drain electrodes are formed on the same plane, so that a gate metal pattern and a data metal pattern may be formed substantially simultaneously using one mask. Thus, the manufacturing process may be simplified.

It will be apparent to those skilled in the art that various modifications and variation can be made in the present invention without departing from the spirit or scope of the invention. Thus, it is intended that the present invention cover the modifications and variations of this invention provided they come within the scope of the appended claims and their equivalents.

What is claimed is:

1. An organic thin film transistor (TFT) substrate, comprising:
gate lines and data lines arranged on a substrate and insulated from each other while crossing each other to define pixel areas;
a gate electrode connected to the gate line;
a source electrode connected to the data line;
a drain electrode facing the source electrode with the gate electrode disposed between the source electrode and the drain electrode;
a gate insulating layer covering the gate electrode and exposing a portion of the source electrode and the drain electrode;
an organic semiconductor layer contacting the source electrode and the drain electrode; and
an organic protective layer disposed on the organic semiconductor layer to protect the organic semiconductor layer.

2. The organic TFT substrate of claim 1, wherein the gate line, the data line, the gate electrode, the source electrode, and the drain electrode are arranged on the same plane.

3. The organic TFT substrate of claim 1, further comprising a bank insulating layer disposed on the gate insulating layer.

4. The organic TFT substrate of claim 3, wherein the organic protective layer is disposed on the organic semiconductor layer and the bank insulating layer.

5. The organic TFT substrate of claim 1, wherein the source electrode and the drain electrode comprise a transparent conductive material.

6. The organic TFT substrate of claim 1, wherein the gate electrode, the source electrode, and the drain electrode comprise:
a first conductive layer comprising a transparent conductive material; and
a second conductive layer disposed on the first conductive layer and comprising an opaque material.

7. The organic TFT substrate of claim 3, wherein the bank insulating layer comprises a photosensitive organic substance.

8. The organic TFT substrate of claim 7, wherein the bank insulating layer is treated with fluorine plasma.

9. The organic TFT substrate of claim 2, further comprising a pixel electrode disposed on the organic protective layer and connected to the drain electrode.

10. The organic TFT substrate of claim 1, wherein the insulating layer comprises an inorganic insulating substance or an organic insulating substance.

11. The organic TFT substrate of claim 1, wherein the organic semiconductor layer comprises a conjugated polymer derivative material.

12. The organic TFT substrate of claim 1, wherein the gate lines are spaced apart from each other with the data lines disposed therebetween, the gate lines being interconnected by a gate bridge insulated from the data lines.

13. A method of manufacturing an organic TFT substrate, the method comprising:
forming gate lines, data lines, a gate electrode, a source electrode, and a drain electrode on the same plane of a substrate;
forming a gate insulating layer covering the gate electrode and exposing a portion of the source electrode and the drain electrode;
forming an organic semiconductor layer that contacts the source electrode and the drain electrode; and
forming an organic protective layer on the organic semiconductor layer.

14. The method of claim 13, further comprising forming a bank insulating layer on the gate insulating layer, the source electrode, and the drain electrode.

15. The method of claim 13, wherein the gate electrode, the source electrode, and the drain electrode comprise the same material.

16. The method of claim 15, wherein the gate electrode, the source electrode, and the drain electrode comprise a transparent conductive material.

17. The method of claim 13, wherein the gate electrode, the source electrode, and the drain electrode comprise:
a first conductive layer comprising a transparent conductive material; and
a second conductive layer disposed on the first conductive layer and comprising an opaque material.

18. The method of claim 14, wherein the bank insulating layer comprises a photosensitive organic substance.

19. The method of claim 18, further comprising treating the bank insulating layer with fluorine plasma.

20. The method of claim 13, further comprising forming a gate bridge that is insulated from the data lines to interconnect the gate lines, which are spaced apart from each other, the data lines being disposed between the gate lines.
